(19) United States
(12) Patent Application Publication
(10) Pub. No.: US 2016/0260725 A1
(43) Pub. Date: Sep. 8, 2016

(54) SEMICONDUCTOR DEVICE

(71) Applicant: SK hynix Inc., Gyeonggi-do (KR)

(72) Inventor: Sung Wook JUNG, Gyeonggi-do (KR)

(21) Appl. No.: 14/813,675

(22) Filed: Jul. 30, 2015

(30) Foreign Application Priority Data
Mar. 4, 2015 (KR) 10-2015-0030447

(51) Int. Cl. H01L 27/115; H01L 29/792; H01L 29/788; H01L 27/02; H01L 29/10

(52) U.S. Cl. CPC H01L 27/11521; H01L 27/0207; H01L 29/1033; H01L 29/7889; H01L 29/7926; H01L 27/11568

(57) ABSTRACT

Disclosed is a semiconductor device, including: a vertical channel layer formed on a semiconductor substrate; first stack conductive layers stacked on the semiconductor substrate at a predetermined interval to surround one side surface of the vertical channel layer; second stack conductive layers stacked on the semiconductor substrate at the predetermined interval to surround the other side surface of the vertical channel layer; a first charge storage layer disposed between the vertical channel layer and the first stack conductive layers; and a second charge storage layer disposed between the vertical channel layer and the second stack conductive layers.

### CROSS-REFERENCE TO RELATED APPLICATION

The present application claims priority to Korean patent application number 10-2015-0030447, filed on Mar. 4, 2015, the entire disclosure of which is herein incorporated by reference in its entirety.

### BACKGROUND

1. Field

The present invention relates to a semiconductor device, and more particularly, to a semiconductor device including memory cells.

2. Discussion of Related Art

Research to form more memory cells in a predetermined area in a three-dimensional memory block has been conducted. To form more memory cells in a predetermined area, a three-dimensional memory string or memory block, in which memory cells are vertically formed on a substrate, has been suggested.

### SUMMARY

The present invention has been made in an effort to provide a semiconductor device, in which more memory cells may be formed in a predetermined area.

An exemplary embodiment of the present invention provides a semiconductor device, including: a vertical channel layer formed over a semiconductor substrate and extending in a first direction; a first conductive stack extending in the first direction, formed over the semiconductor substrate and surrounding a first side surface of the vertical channel layer, a second conductive stack extending in the first direction, formed over the semiconductor substrate, and surrounding a second side surface of the vertical channel layer; a first charge storage layer disposed between the vertical channel layer and the first conductive stack; and a second charge storage layer disposed between the vertical channel layer and the second conductive stack.

Another exemplary embodiment of the present invention provides a semiconductor device, including: a plurality of vertical channel layers formed over a semiconductor substrate; first stack conductive layers stacked over the semiconductor substrate at a predetermined interval to surround one side surfaces of the vertical channel layers; second stack conductive layers stacked over the semiconductor substrate at the predetermined interval to surround the other side surfaces of the vertical channel layers; first charge storage layers disposed between the vertical channel layers and the first stack conductive layers; and second charge storage layers disposed between the vertical channel layers and the second stack conductive layers.

According to the exemplary embodiments of the present invention, it is possible to form more memory cells in a predetermined area.

The foregoing summary is illustrative only and is not intended to be limiting in any way. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and advantages of the present invention will become more apparent to those of ordinary skill in the art by describing in detail embodiments thereof with reference to the attached drawings in which:

FIG. 1 is a block diagram illustrating a semiconductor device according to an exemplary embodiment of the present invention;

FIGS. 2A and 2B are diagrams for describing a structure of a memory string according to the exemplary embodiment of the present invention;

FIGS. 3A to 3F are diagrams for describing a method of manufacturing a semiconductor device according to an exemplary embodiment of the present invention;

FIG. 4 is a diagram for describing a method of manufacturing a semiconductor device according to another exemplary embodiment of the present invention;

FIG. 5 is a block diagram schematically illustrating a memory system according to an exemplary embodiment of the present invention;

FIG. 6 is a block diagram schematically illustrating a fusion memory device or a fusion memory system performing a program operation according to aforementioned various exemplary embodiment; and

FIG. 7 is a block diagram schematically illustrating a computing system including a flash memory device according to an exemplary embodiment of the present invention.

### DETAILED DESCRIPTION

Hereinafter, an embodiment of the present invention will be described with reference to the accompanying drawings in detail. However, the present invention is not limited to an embodiment disclosed below and may be implemented in various forms and the scope of the present invention is not limited to the following embodiments. Rather, the embodiment is provided to more sincerely and fully disclose the present invention and to completely transfer the spirit and scope of the present invention to those skilled in the art to which the present invention pertains.

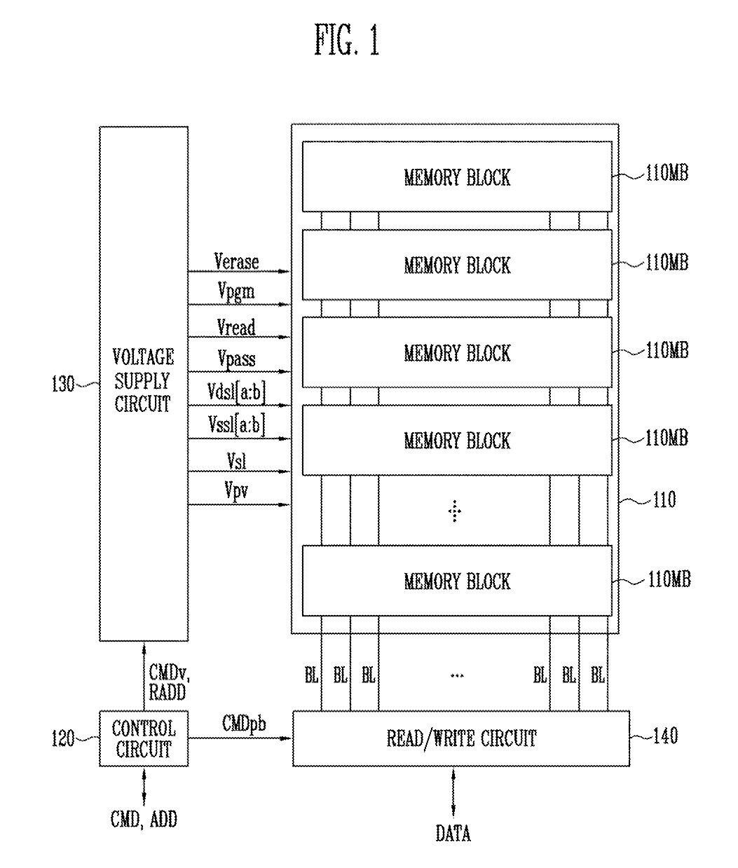

FIG. 1 is a block diagram illustrating a semiconductor device according to an exemplary embodiment of the present invention.

Referring to FIG. 1, a semiconductor memory device includes a memory array 110 and operating circuits 120 to 140. The memory array 110 includes a plurality of memory blocks 110MB. Each of the memory blocks includes a plurality of memory cells. For a flash memory device, the memory block includes flash memory cells. For example, the memory block may include a floating gate formed of polysilicon or flash memory cells including a charge storage layer formed of a nitride layer.

Particularly, the memory block may include memory strings connected with bit lines, respectively, and connected to a common source line in parallel. The memory strings may be formed in a 2D structure or a 3D structure on a semiconductor substrate. The memory block including the 3D structural memory string will be described in more detail.

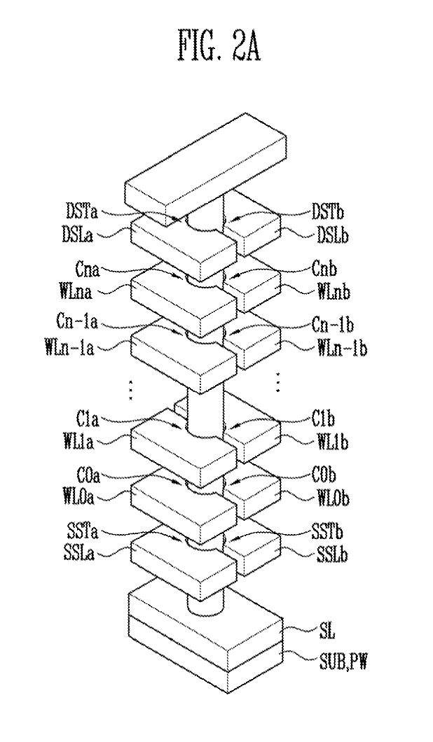

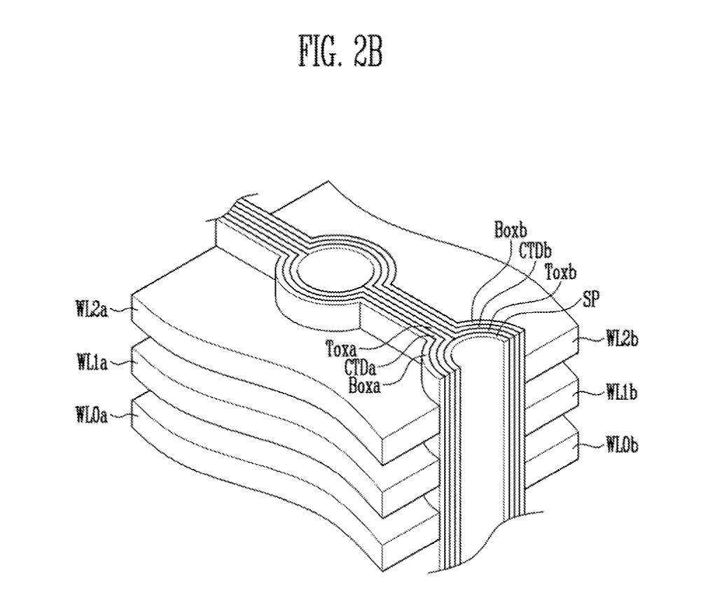

FIGS. 2A and 2B are diagrams for describing a structure of the memory string according to the exemplary embodiment of the present invention.

Referring to FIGS. 2A and 2B, a P-well PW may be formed on a semiconductor substrate SUB. The P-well PW may be formed by injecting first impurities into the semiconductor substrate SUB. The first impurities may include group III elements of the periodic table. A common source area SL is formed in the P-well PW. The common source area SL becomes a common source line. The common source area SL may be formed by injecting second impurities into the substrate SUB or the P-well PW. The second impurities may include group V elements of the periodic table.

A plurality of vertical channel layers SP is formed on the semiconductor substrate SUB or the common source area SL. Further, bit lines BL (shown in FIG. 1) are connected to upper parts of the plurality of vertical channel layers SP.

First stack conductive layers SSLa, WL0a to WLna, and DSLa are stacked on the semiconductor substrate SUB at a predetermined interval so as to surround one-side surfaces of the vertical channel layers SP. Second stack conductive layers SSLb, WL0b to WLnb, DSLb are stacked on the semiconductor substrate SUB at a predetermined interval so as to surround other-side surfaces of the vertical channel layers SP.

Oxide-Nitride-Oxide (ONO) structures are formed between the first stack conductive layers SSLa, WL0a to WLna, and DSLa and the vertical channel layers SP and between the second stack conductive layers SSLb, WL0b to WLnb, Dab and the vertical channel layers SP, respectively. Particularly, a charge storage layer CTDa formed of a nitride layer is disposed between the first stack conductive layers SSLa, WL0a to WLna, and DSLa and the vertical channel layers SP. A charge storage layer CTDa formed of a nitride layer is disposed between each of the second stack conductive layers SSLb, WL0b to WLnb, DSLb and each of the vertical channel layers SP.

A blocking insulating layer Boxa is provided between each of the first stack conductive layers SSLa, WL0a to WLna, and DSLa and the charge storage layer CTDa. A blocking insulating layer Boxb is disposed between each of the second stack conductive layers SSLb, WL0b to WLnb, DSLb and the charge storage layer CTDb. Each of blocking insulating layers Boxa and Boxb may be formed of an insulating layer, such as an oxide layer. A tunnel insulating layer Taxa may be disposed between the charge storage layer CTDA and each of the the vertical channel layers SP. A tunnel insulating layer Toxb may be disposed between the charge storage layer CTDb and each of the vertical channel layers SP. Each of the tunnel insulating layers Taxa and Toxb may be formed of an insulating layer, such as an oxide layer.

An interval between the vertical channel layers SP may be larger than, equal to, or smaller than a diameter of the vertical channel layer SP. The vertical channel layer SP may be formed in a cylindrical shape. In another embodiment, the vertical channel layer SP may also be formed in a quadrangular pillar shape.

The topmost conductive layer DSLa and the bottommost conductive layer SSLa of the first stack conductive layers SSLa, WL0a to WLna, and DSLa, and the topmost conductive layer DSLb and the bottommost conductive layer SSLb of the second stack conductive layers SSLb, WL0b to WLnb, and DSLb may serve as select lines DSLa, DSLb, SSLa, and SSLb, respectively. The remaining conductive layers WL0a to WLna of the first stack conductive layers SSLa, WL0a to WLna, and DSLa, and the remaining conductive layers WL0b to WLnb of the second stack conductive layers SSLb, WL0b to WLnb, and DSLb may serve as word lines, respectively.

The first stack conductive layers SSLa, WL0a to WLna, and DSLa are electrically and physically separated from the second stack conductive layers SSLb, WL0b to WLnb, and DSLb. In an embodiment, the first stack conductive layers SSLa, WL0a to WLna, and DSLa and the second stack conductive layers SSLb, WL0b to WLnb, and DSLb may belong to different memory blocks.

The select transistors DSTa, DSTb, SSTa, and SSTb and the memory cells C0a to Cna and C0b to Cnb are formed in regions in which the first stack conductive layers SSLa, WL0a to WLna, and DSLa overlap the vertical channel layer SP, and in regions in which the second stack conductive layers SSLb, WL0b to WLnb, and DSLb overlap the vertical channel layer SP.

According to the aforementioned structure, two adjacent memory blocks make one pair. For example, the memory strings included in a first memory block and the memory strings included in a second memory block are arranged around the same vertical channel layer SP. That is, the memory strings included in one memory block and the memory strings included in the different memory block are alternately connected to the bit lines.

As described above, the memory cells are formed on one side surface and the other side surface of the vertical channel layer so that more memory cells may be formed in the same area.

Referring to FIGS. 1 and 2A, the operating circuits 120 to 140 are configured to perform a program loop, an erase loop, and a read operation of the memory cells C0a connected to a selected word line WL0a. The program loop includes a program operation and a verification operation, and the erase loop includes an erase operation and a verification operation. The operation circuits 120 to 140 may perform the program operation and/or a post program operation for adjusting erase levels at which the threshold voltages of the memory cells are distributed after the erase loop.

To perform the program loop, the erase loop, and the read operation, the operation circuit 120 to 140 selectively output operation voltages Verase, Vpgm, Vread, Vpass, Vdsl[a:b], Vssl[a:b], Vsl, and Vpv to the local lines SSLa, WL0a˜WLna, and DSLa of the selected memory block and the common source line SL, and control precharge/discharge of the bit lines BL or sense a current flow or a voltage change of the bit lines BL.

For a NAND flash memory device, the operation circuit includes a control circuit 120, a voltage supply circuit 130, and a read/write circuit 140. Each constituent element will be described in detail below.

The control circuit 120 controls the voltage supply circuit 130 so that the operation voltages Verase, Vpgm, Vread, Vpass, Vdsl[a:b], Vssl[a:b], Vsl, and Vpv for performing the program loop, the erase loop, and the read operation are generated at desired levels and the generated operation voltages are applied to the local lines SSLa, WL0a to WLna, and DSLa of the selected memory block and the common source line SL in response to a command signal CMD input from the outside. To this end, the control circuit 120 may output a voltage control signal CMDv and a row address signal RADD generated according to an address signal ADD to the voltage supply circuit 130.

Furthermore, the control circuit controls the read/write circuit 140 so as to control precharge/discharge of the bit lines BL according to data to be stored in the memory cells in order to perform the program loop, the erase loop, and the read operation or sense a current flow or a voltage change of the bit lines BL during the read operation or the verification operation. To this end, the control circuit 120 may output an operation control signal CMBpb to the read/write circuit 140.

The voltage supply circuit 130 generates the necessary operation voltages Verase, Vpgm, Vread, Vpass, Vdsl[a:b], Vssl[a:b], Vsl, and Vpv according to the program loop, the erase loop, and the read operation of the memory cells according to the control signal CMDv of the control circuit 20. The operation voltages may include the erase voltage Verase, the program voltage Vpgm, the read voltage Vread, the pass voltage Vpass, the select voltages Vdsl[a:b] and Vssl[a:b], and the common source voltage Vsl. Further, the voltage supply circuit 130 outputs the operation voltages to the local lines SSLa, WL0a to WLna, and DSLa of the selected memory block and the common source line SL in response to the row address signal RADD.

The read/write circuit 140 may include each of a plurality of page buffers (not shown) connected with the memory array 110 through the bit lines BL. Particularly, the page buffers may be connected to the bit lines BL, respectively. That is, one page buffer may be connected to one bit line. During the program operation, the page buffers of the read/write circuit 140 selectively precharge the bit lines BL according to the control signal CMDpb of the control circuit 120 and data DATA to be stored in the memory cells. During a program verification operation or the read operation, the page buffers of the read/write circuit 140 may precharge the bit lines BL, and then sense a voltage change or currents of the bit lines BL and latch data read from the memory cell according to the control signal CMDpb of the control circuit.

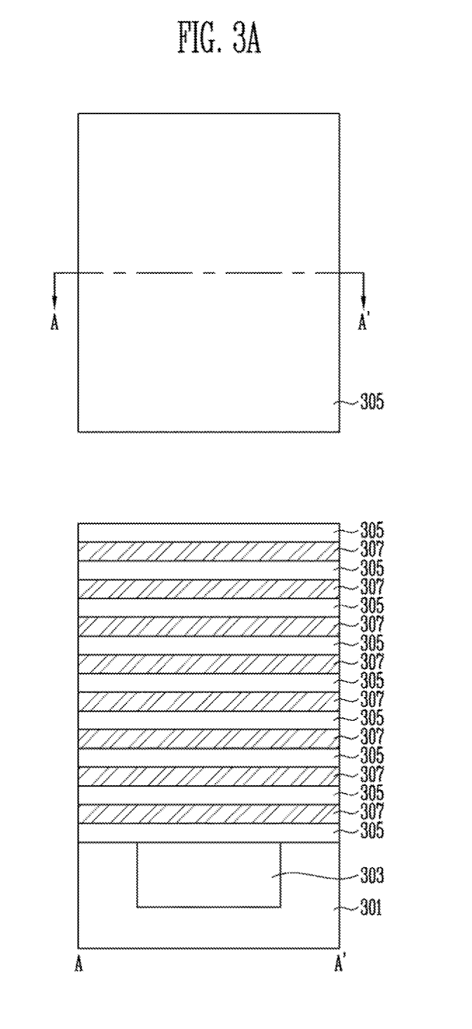

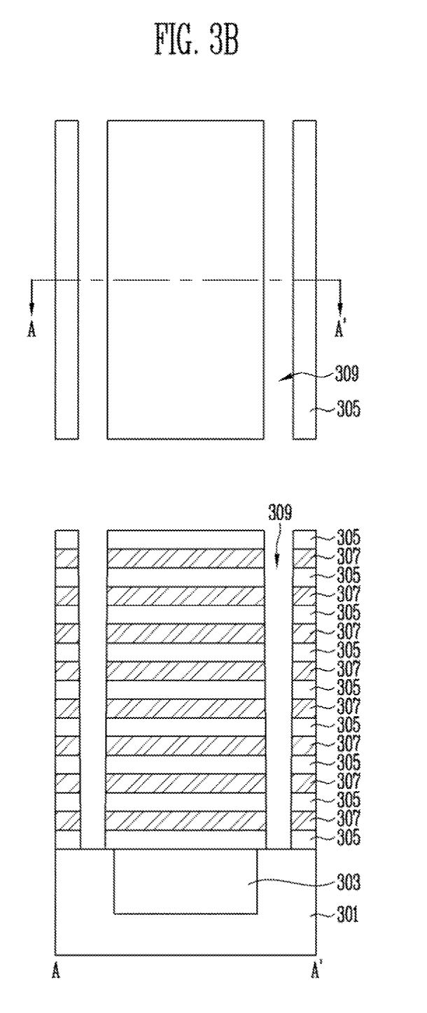

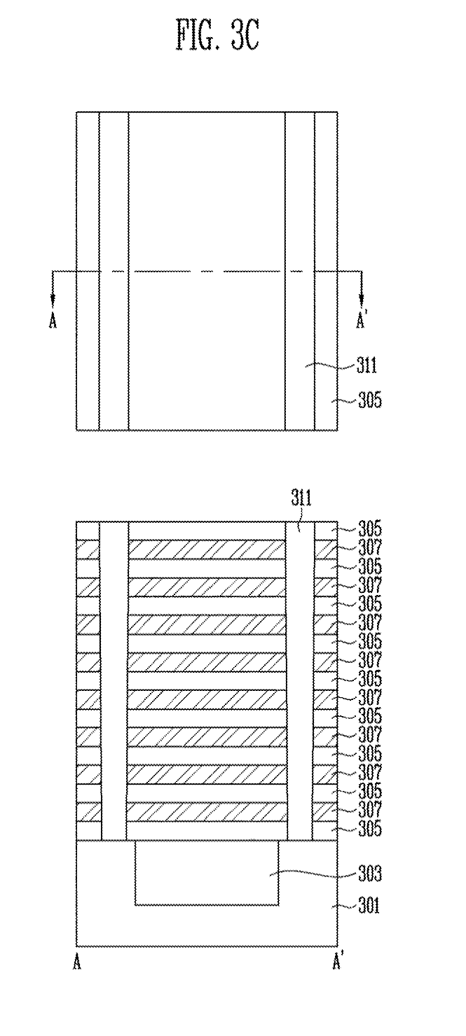

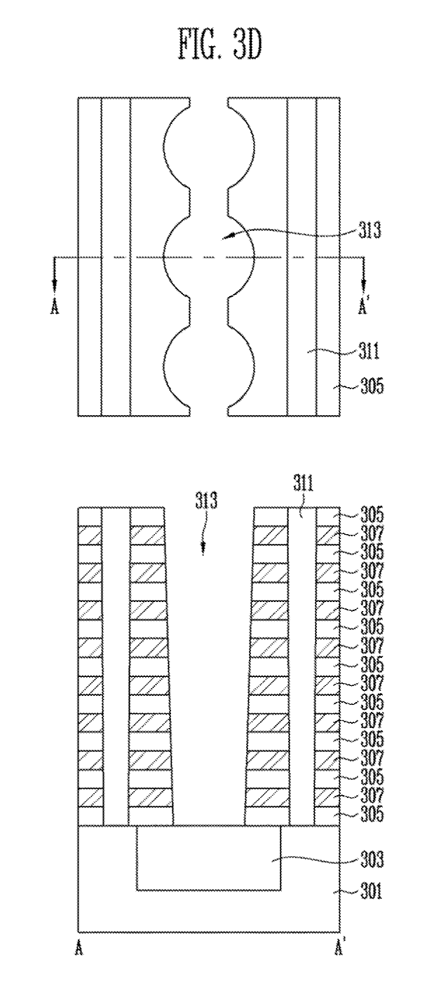

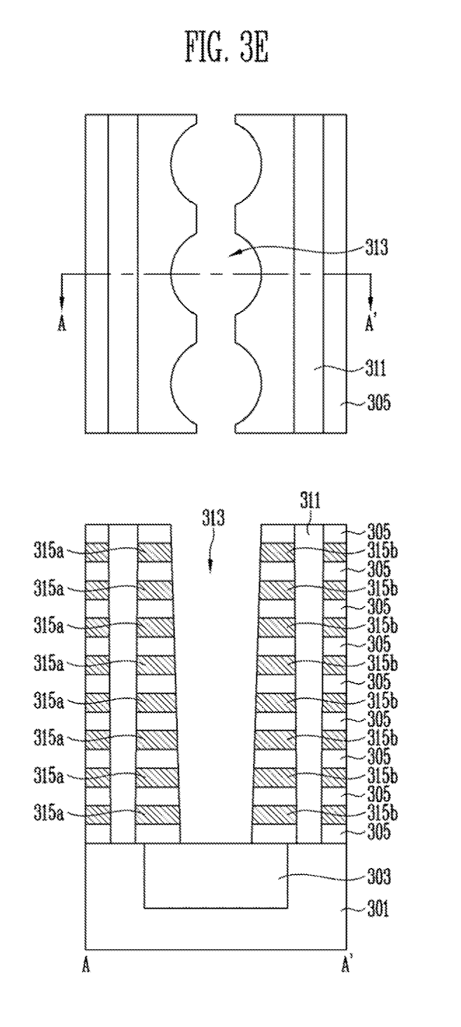

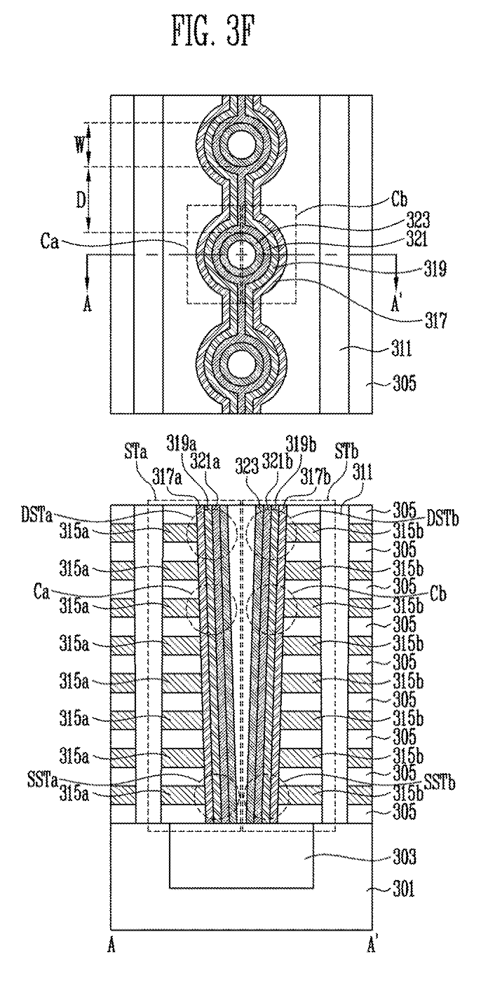

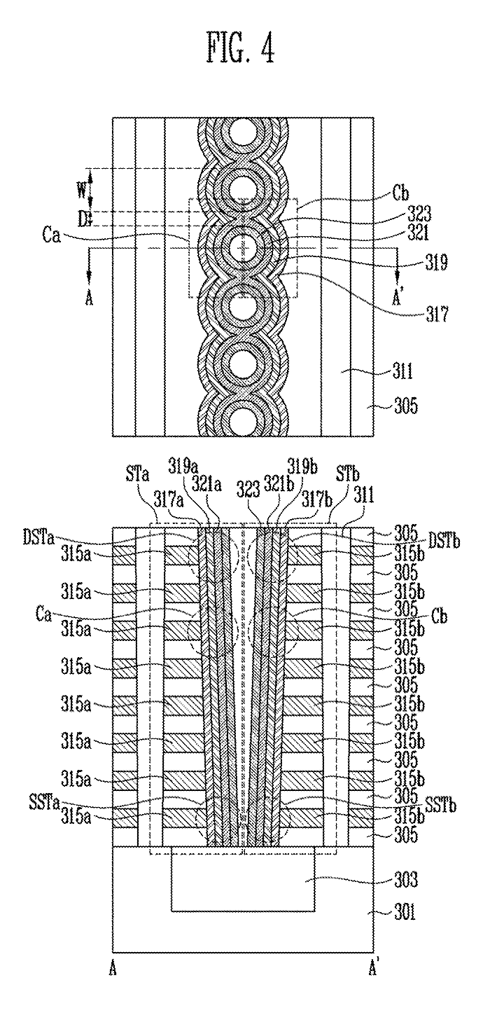

Hereinafter, a method of manufacturing a semiconductor memory device according to an exemplary embodiment of the present invention will be described. FIGS. 3A to 3F are diagrams for describing a method of manufacturing a semiconductor device according to an exemplary embodiment of the present invention. FIG. 4 is a diagram for describing a method of manufacturing a semiconductor device according to another exemplary embodiment of the present invention.

Referring to FIG. 3A, a common source area 303 to be used as a common source line is formed on a semiconductor substrate 301. The common source area 303 may be formed by injecting impurities into the semiconductor substrate 301.

A first insulating layer 305 and a second insulating layer 307 are alternately formed on the semiconductor substrate 301. The second insulating layer 307 is a sacrificial insulating layer that is formed to secure an area in which a conductive layer is formed, and is removed in a subsequent process. A thickness of a conductive layer, which is formed between the first insulating layers 305 in a subsequent process, is determined according to a thickness of the second insulating layer 307. The first insulating layer 305 may be formed of an oxide layer, and the second insulating layer 307 may be formed of a nitride layer.

Referring to FIG. 3B, predetermined areas of the first insulating layer 305 and the second insulating layer 307 are etched. A slit 309 is formed at an etched portion, and a memory block area may be defined by the slit 309. The slit 309 may be formed in a line shape in a direction crossing a bit line or in a direction parallel to a word line.

Referring to FIG. 3C the slit 309 is filled with a third insulating layer 311. Particularly, an oxide layer 311 is formed on an entire structure so that the slit 309 is filled, and then an upper surface of the oxide layer 311 may be planarized by performing a chemical mechanical polishing process.

Referring to FIG. 3D, a hole shaped like a line is formed by etching predetermined areas of the first and second insulating layers 305 and 307 between the third insulating layers 311 filled in the slits. The hole 313 is formed so that the first and second insulating layers 305 and 307 are divided into both sides between the third insulating layers 311. The hole 313 is formed so as to define the regions in which vertical channel layers are to be formed, and the common source area 303 of the semiconductor substrate 301 is exposed through the hole 313. The hole 313 is formed in a circular or quadrangular shape in the areas in which the vertical channel layers are to be formed and may be formed in a line shape with a small width between the circular or quadrangular etched areas.

Referring to FIG. 3E, the second insulating layer 307 is removed, and conductive layers 315a and 315b are formed in the space from which the second insulating layer is removed. Particularly, a conductive layer is formed so that the space from which the second insulating layer is removed, is filled by a Chemical Vapor Deposition (CVD) method an Atomic Layer Deposition (ALD) method. Then, a blanket etch process may be performed to remove the conductive layers deposited on an upper part and a lateral wall of the first insulating layer 305. As a result, conductive layers 315a and 315b are formed in the space from which the second insulating layer is removed. The conductive layers 315a and 315b may serve as select lines and word lines. Particularly, the conductive layers 315a and the conductive layers 315b serve as select lines and word lines belonging to different memory blocks, respectively.

Referring to FIG. 3F, a blocking insulating layer 317, a charge storing layer 319, a tunnel insulating layer 321, and a vertical channel layer 323 are sequentially formed on lateral walls of the first insulating layer 305 and the conductive layers 315a and 315b inside the hole 313 (shown in FIG. 3E). A tunnel insulating layer 321a formed on lateral walls of the first insulating layer 305 and the conductive layers 315a, is in contact with a tunnel insulating layer 321b formed on lateral walls of the first insulating layer 305 and the conductive layers 315b. As a result, the vertical channel layers 323 are formed within the hole 313 and are not connected with each other.

The vertical channel layers 323 may be formed in a cylindrical shape or a quadrangular pillar shape according to a shape and a width of the hole 313. In an embodiment, an interval D of the vertical channel layers 323 may be larger than a diameter W of the vertical channel layer 323 according to the shape of the hole 313.

Referring to FIG. 4, the interval D of the vertical channel layers 323 may be smaller than the diameter W of the vertical channel layer 323. According to the aforementioned method, a drain select transistor DSTa, memory cells Ca, and a source select transistor SSTa are formed on one side surface of the vertical channel layer 323, and a drain select transistor DSTb, memory cells Cb, and a source select transistor SSTb are formed on the other side surface of the vertical channel layer 323. The drain select transistor DSTa, the memory cells Ca, and the source select transistor SSTa are included in a first memory block, and the drain select transistor DSTb, the memory cells Cb, and the source select transistor SSTb may be included in a second memory block different from the first memory block.

The different select transistors and memory cells are formed on one side surface and the other side surface of the vertical channel layer 323, so that it is possible to form more devices in a predetermined area.

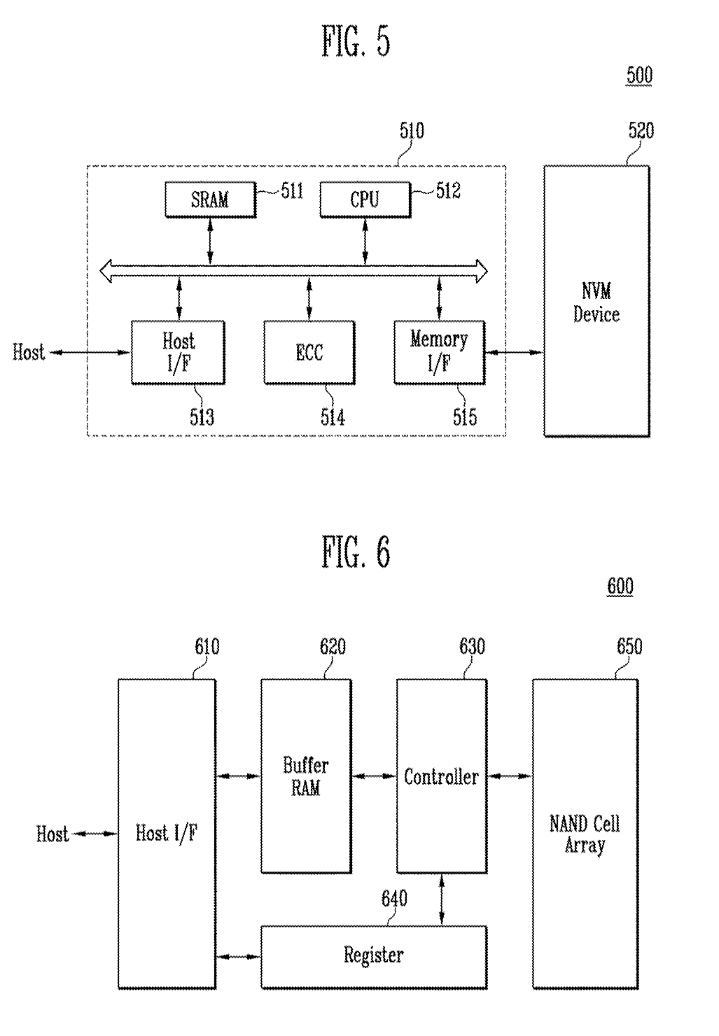

FIG. 5 is a block diagram schematically illustrating a memory system according to an exemplary embodiment of the present invention. Referring to FIG. 5, a memory system 500 according to the exemplary embodiment of the present invention includes a nonvolatile memory device 520 and a memory controller 510.

The nonvolatile memory device 520 may correspond to the memory device described with reference to FIG. 1, and may be connected to the memory array and the operation circuit as described with reference to FIG. 1. The memory controller 510 may be configured to control the nonvolatile memory device 520. A memory card or a semiconductor disk device (Solid State Disk: SSD) may be provided in addition to the nonvolatile memory device 520 and the memory controller 510. An SRAM 511 is used as an operation memory of the processing unit 512. The host interface 513 includes a data exchange protocol of a host connected with the memory system 500. An error correction block 514 detects and corrects an error included in data read from a cell region of the nonvolatile memory device 520. A memory interface 515 interfaces with the nonvolatile memory device 520 of the present invention. The processing unit 512 performs a general control operation for the data exchange of the memory controller 510.

Although it is not illustrated in the drawings, a ROM (not shown) storing code data for interfacing with the host may be further provided. The nonvolatile memory device 520 may also be provided in a form of a multi-chip package including a plurality of flash memory chips. The memory system 500 of the present invention may be provided as a highly reliable storage medium with an improved operation characteristic. The flash memory device of the present invention may be included in a memory system, such as a semiconductor disk device (an SSD). In this case, the memory controller 510 may be configured to communicate with an external device for example, the host, through one of various interface protocols, such as USB, MMC, PCI-E, SATA, PATA, SCSI, ESDI, and IDE.

FIG. 6 is a block diagram schematically illustrating a fusion memory device or a fusion memory system performing a program operation. For example, the technical characteristics of the present invention may be applied to an OneNAND flash memory device 600, as a fusion memory device.

The OneNAND flash memory device 600 includes a host interface 610 for exchanging various information between device units or modules using different protocols, a buffer RAM 620 including a code for driving the memory device or temporally storing data, a controller 630 configured to control a read operation and a program operation etc. in response to a control signal and a command provided from the outside, a register 640 storing data, such as a command, an address, and configuration defining a system operating environment within the memory device, and a NAND flash cell array 650 formed of are operating circuit including a nonvolatile memory cell and a page buffer. The OneNAND flash memory device programs data in response to a write request from the host.

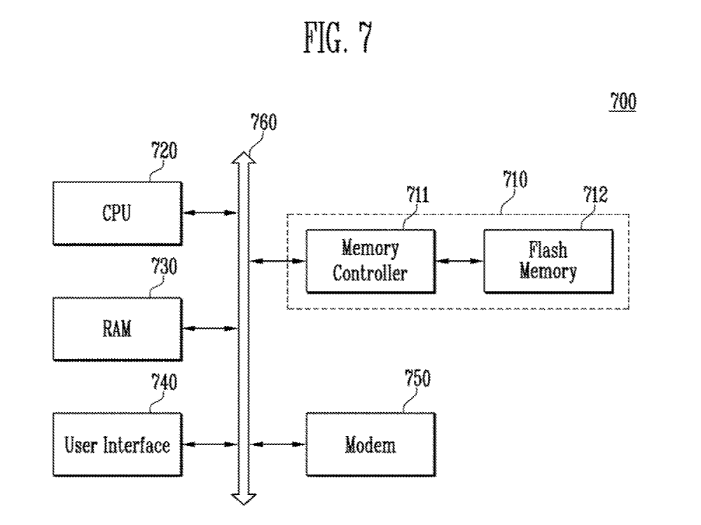

FIG. 7 schematically illustrates a computing system including a flash memory device 712 according to the embodiment of the present invention. A computing system 700 according to the present invention includes a microprocessor 720 electrically connected to a system bus 760, a RAM 730, a user interface 740, a modem 750, such as a baseband chipset, and a memory system 710. In a case in which the computing system 700 according to the present invention is a mobile device, a battery (not shown) for supplying an operating voltage of the computing system 700 may be further provided. Although is not illustrated in the drawings, the computing system 700 according to the present invention may further include an application chipset, a Camera Image Processor (CIS), a mobile DRAM, and the like. The memory system 710 may further include, for example, an SSD using the nonvolatile memory described with reference to FIG. 1, to store data. In an embodiment, the memory system 710 may be provided as a fusion flash memory (for example, a OneNAND flash memory).

What is claimed is:

1. A semiconductor device, comprising:
a vertical channel layer formed over a semiconductor substrate and extending in a first direction;
a first conductive stack extending in the first direction, formed over the semiconductor substrate, and surrounding a first side surface of the vertical channel layer;
a second conductive stack extending in the first direction, formed over the semiconductor substrate, and surrounding a second side surface of the vertical channel layer;
a first charge storage layer disposed between the vertical channel layer and the first conductive stack; and
a second charge storage layer disposed between the vertical channel layer and the second conductive stack.

2. The semiconductor device of claim 1, wherein the vertical channel layer is formed in a cylindrical shape.

3. The semiconductor device of claim 1, wherein the first conductive stack and the second conductive stack are electrically and physically isolated from each other.

4. The semiconductor device of claim 1, wherein the conductive stack is included in a first memory block, and the second conductive stack is included in a second memory block.

5. The se conductor device of claim 1, further comprising:
a first tunnel insulating layer disposed between the vertical channel layer and the first charge storage layer;
a second tunnel insulating layer disposed between the vertical channel layer and the second charge storage layer;
a first blocking insulating layer disposed between the first charge storage layer and the first conductive stack; and
a second blocking insulating layer disposed between the second charge storage layer and the second conductive stack.

6. The semiconductor device of claim 1, wherein a common source area is formed in the semiconductor substrate, and
wherein a lower part of the vertical channel layer is connected with the common source area.

7. The semiconductor device of claim 6, wherein an upper part of the vertical channel layer is connected with a bit line.

8. The semiconductor device of claim 1, wherein the first conductive stack includes a first topmost conductive layer, a first bottommost conductive layer, and first middle conductive layer,
wherein the second conductive stack includes a second topmost conductive layer, a second bottommost conductive layer, and a second middle conductive layer,
wherein at least one of the first topmost conductive layer and the first bottommost conductive is a first select line,
wherein at least one of the second topmost conductive layer and the second bottommost conductive is a second select line, and
wherein the first middle conductive layer and the second middle conductive layer are first and second word lines, respectively.

9. A semiconductor device, comprising:
a plurality of vertical channel layers formed over a semiconductor substrate;
first stack conductive layers stacked over the semiconductor substrate at a predetermined interval to surround one side surfaces of the vertical channel layers;
second stack conductive layers stacked over the semiconductor substrate at the predetermined interval to surround the other side surfaces of the vertical channel layers;
first charge storage layers disposed between the vertical channel layers and the first stack conductive layers; and
second charge storage layers disposed between the vertical channel layers and the second stack conductive layers.

10. The semiconductor device of claim 9, wherein an interval between the vertical channel layers is larger than a diameter of each of the vertical channel layers.

11. The semiconductor device of claim 9, wherein an interval between the vertical channel layers is smaller than a diameter of each of the vertical channel layers.

12. The semiconductor device of claim 9, wherein each of the vertical channel layers is formed in a cylindrical shape.

13. The semiconductor device of claim 9, wherein the first stack conductive layers and the second stack conductive layers are electrically and physically isolated from each other.

14. The semiconductor device of claim 9, wherein the first stack conductive layers are included in a first memory block, and the second stack conductive layers are included in a second memory block.

15. The semiconductor device of claim 9 further comprising:
tunnel insulating layers disposed between the vertical channel layers and the first charge storage layers and between the vertical channel layers and the second charge storage layers; and
blocking insulating layers disposed between the first charge storage layers and the first stack conductive layers and between the second charge storage layers and the second stack conductive layers.

16. The semiconductor device of claim 9, wherein a common source area is formed in the semiconductor substrate, and
wherein lower parts of the vertical channel layers are connected with the common source area.

17. The semiconductor device of claim 16, wherein upper parts of the vertical channel layers are connected with bit lines, respectively.

18. The semiconductor device of claim 9, wherein a topmost conductive layer and a bottommost conductive layer among the first stack conductive layers and a topmost conductive layer and a bottommost conductive layer among the second stack conductive layers are select lines, and
wherein the remaining conductive layers of the first stack conductive layers and the remaining conductive layers of the second stack conductive layers are word lines.

19. A semiconductor device, comprising:
a substrate including first and second memory blocks;
a first conductive stack extending in a first direction from the substrate included in the first memory block;
a second conductive stack extending in the first direction from the substrate included in the second memory block;
first and second vertical channel layers each extending in the first direction from the substrate between the first and the second conductive stacks;
a first charge storage layer extending from between the first vertical channel layer and the first conductive stack to between the second vertical channel layer and the first conductive stack; and
a second charge storage layer extending from between the first vertical channel layer and the second conductive stack to between the second vertical channel layer and the second conductive stack.

20. The semiconductor device of claim 19, further comprising:
a first tunnel insulating layer extending from between the first vertical channel layer and the first charge storage layer to between the second vertical channel layer and the first charge storage layer,
a second tunnel insulating layer extending from between the first vertical channel layer and the second charge storage layer to between the second vertical channel layer and the second charge storage layer;
a first blocking insulating layer extending between the first charge storage layer and the first conductive stack; and
a second blocking insulating layer extending between the second charge storage layer and the second conductive stack.

21. The semiconductor device of claim 20,
wherein the first and the second tunnel insulating layers are coupled to each other.
